(19) United States
(12) Patent Application Publication
(10) Pub. No.: US 2015/0069537 A1
(43) Pub. Date: Mar. 12, 2015

(54) PACKAGE-ON-PACKAGE SEMICONDUCTOR SENSOR DEVICE

(71) Applicants: Wai Yew Lo, Petaling Jaya (MY); Stanley Job Doraisamy, Setapak (MY); Lan Chu Tan, Singapore (SG)

(72) Inventors: Wai Yew Lo, Petaling Jaya (MY); Stanley Job Doraisamy, Setapak (MY); Lan Chu Tan, Singapore (SG)

(21) Appl. No.: 14/020,840

(22) Filed: Sep. 8, 2013

(51) Int. Cl. B81B 7/00; H01L 23/495; B81C 1/00

(52) U.S. Cl. CPC B81B 7/007; B81C 1/00301; H01L 23/49503; B81B 2201/0264; B81B 2201/0235
USPC 257/415; 438/51

(57) ABSTRACT

A semiconductor sensor device has a MCU die and an acceleration-sensing die mounted on a die paddle of a lead frame. The MCU die is connected to leads of the lead frame with first bond wires and the acceleration-sensing die is connected to the MCU die with second bond wires. An interposer is flip-chip mounted on a top surface of the MCU die. The MCU die, acceleration-sensing die and a portion of the interposer are covered with a molding compound. A pre-packaged pressure sensor is flip-chip mounted on a top, exposed surface of the interposer. The interposer provides electrical connection between the pre-packaged pressure sensor and the MCU die.

### BACKGROUND OF THE INVENTION

The present invention relates generally to semiconductor packaging and, more particularly to a package-on-package type semiconductor pressure sensor.

Semiconductor sensor devices, such as pressure sensors, are well known. Such devices use semiconductor pressure-sensing dies. These dies are susceptible to mechanical damage during packaging and environmental damage when in use, and thus they must be carefully packaged. Further, pressure-sensing dies, such as piezo resistive transducers (PRTs) and parameterized layout cells (P-cells), do not allow full encapsulation because that would impede their functionality.

FIG. 1(A) shows a cross-sectional side view of a conventional semiconductor sensor device 100 having a metal lid 104 and a pressure sensor die 106. FIG. 1(B) shows a perspective top view of the sensor device 100 without the lid 104 and without a gel 114 coating over the pressure sensor die, and FIG. 1(C) shows a perspective top view of the lid 104.

As shown in FIG. 1, the pressure sensor die (P-cell) 106, an acceleration-sensing die (G-cell) 108, and a micro-controller unit die (MCU) 110 are mounted to a flag 112 of a lead frame, electrically connected to package leads 118 by bond wires (not shown), and covered by the pressure-sensitive gel 114, which enables the pressure of the ambient atmosphere to reach the pressure-sensitive active region on the top side of the P-cell 106, while protecting all of the dies 106, 108, 110 and the bond wires from mechanical damage during packaging and environmental damage (e.g., contamination and/or corrosion) when in use. The entire die/substrate assembly is encased in a molding compound 102 and covered by the lid 104. The lid 104 has a vent hole 116 that exposes the gel-covered P-cell to ambient atmospheric pressure outside the sensor device.

One problem with the design of sensor device 100 is the high manufacturing cost due to the use of a pre-molded lead frame, the metal lid 104, and the large volume of pressure-sensitive gel 114. Accordingly, it would be advantageous to have a more-economical way to assemble a pressure sensor device.

### BRIEF DESCRIPTION OF THE DRAWINGS

Embodiments of the present disclosure are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows a conventional packaged semiconductor sensor device having a metal lid;

FIG. 2 shows a semiconductor sensor device in accordance with an embodiment of the disclosure; and

FIGS. 3(A)-3(J) illustrate one possible process for manufacturing the sensor device of FIG. 2.

### DETAILED DESCRIPTION OF THE INVENTION

Detailed illustrative embodiments of the present disclosure are disclosed herein. However, specific structural and functional details disclosed herein are merely representative for purposes of describing example embodiments of the present disclosure. Embodiments of the present disclosure may be embodied in many alternative forms and should not be construed as limited to only the embodiments set forth herein. Further, the terminology used herein is for the purpose of describing particular embodiments only and is not intended to be limiting of example embodiments of the disclosure.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method of assembling a semiconductor sensor device, and in another embodiment is the resulting semiconductor sensor device. A micro controller unit (MCU) die is mounted on a substrate or lead frame. An interposer is mounted on the MCU die. The MCU die and a first portion of the interposer are encapsulated in a molding compound, leaving a second portion of the interposer exposed. A pre-packaged pressure sensor then is mounted onto the exposed, second portion of the interposer. The interposer includes through metal vias or other wiring patterns that allow the interposer to provide electrical interconnection between the MCU die and the pre-packaged pressure sensor.

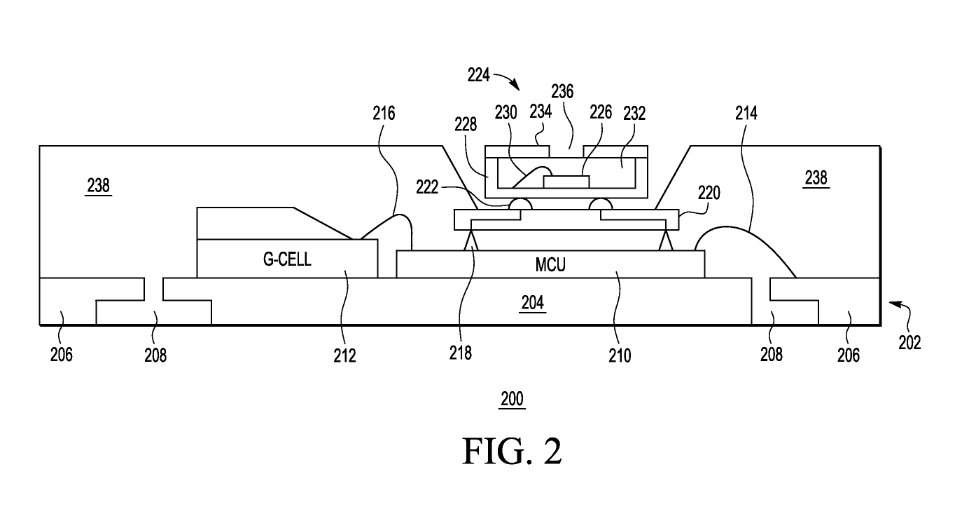

FIG. 2 shows a cross-sectional side view of a packaged semiconductor sensor device 200 in accordance with an embodiment of the present invention. The exemplary configuration of the sensor device 200 forms a no-leads type package such as a quad flat no-leads (QFN) package. Note that alternative embodiments are not limited to QFN packages, but can be implemented for other package types, such as (without limitation) ball grid array (BGA) packages, quad flat packages (QFP) or other leaded packages.

The sensor device 200 comprises a lead frame 202 having a die paddle 204 and multiple metal leads 206 separated by and embedded within an electrically insulating molding compound 208. The lead frame 202 may be formed of copper, an alloy of copper, a copper plated iron/nickel alloy, plated aluminum, or the like. Often, copper leads are pre-plated first with a nickel base layer, then a palladium mid-layer, and finally with a very thin, gold upper layer. The molding compound 208 may be an epoxy or other suitable material. The lead frame 202 and molding compound 208 together comprise a pre-molded lead frame that may be formed and obtained from a supplier as opposed to being formed at the sensor device assembly site.

The lead frame 202 functions as a substrate to which other elements of the sensor device 200 are mounted. More specifically, an MCU die 210 and an acceleration-sensing die (a.k.a. G-cell) 212 are mounted on and attached to the die paddle 204. Wire-bond pads on the MCU 210 are electrically connected to one or more of the leads 206 with bond wires 214, and one or more other wire-bond pads on the MCU 210 are electrically connected to one or more wire-bond pads on the G-cell 212 with bond wires 216. The G-cell 212, which is an optional component, is designed to sense gravity or acceleration in one, two, or three axes, depending on the particular implementation. The bond wires 214 and 216 are formed from a conductive material such as aluminium, silver, gold, or copper, and may be either coated or uncoated. Note that, in alternative designs, the MCU 210 and/or G-cell 212 can be electrically connected to the leads 206 using suitable flip-chip, solder-bump techniques instead of or in addition to wire bonding.

Conventional, electrically insulating die-attach adhesive (not shown) may be used to attach the MCU 210 and G-cell 212 to the die paddle 204. Those skilled in the art will understand that suitable alternative means, such as die-attach tape, may be used to attach some or all of these dies.

An interposer 220 is mounted on a top surface of the MCU 210 with bump interconnections 218, and a pre-packaged pressure sensor 224 is mounted on a top surface of the interposer 220 with other bump interconnections 222. In one implementation, the interposer 220 comprises a single metal layer sandwiched between two insulating layers with one or more metal vias through the insulating layers. The metal vias and patterned metal features in the metal layer along with corresponding bump interconnections 218 and 222 provide electrical interconnections between the MCU 210 and the pre-packaged pressure sensor 224. In another embodiment, the interposer 220 may comprise a substrate formed of a non-conductive material (e.g., ceramic) with through metal vias.

The pre-packaged pressure sensor 224, which may itself be a BGA package, comprises a pressure-sensing die (i.e., P-cell) 226 mounted within a package housing 228. The P-cell 226 is designed to sense ambient atmospheric pressure. The pre-packaged pressure sensor 224 may take various forms, such as the P-cell 226 being electrically connected to leads (not explicitly shown in FIG. 2) in the package housing 228 with bond wires 230. A pressure-sensitive gel 232 covers the P-cell 226 and bond wires 230 and fills the cavity of package housing 228. Note that, in alternative implementations, less gel material 232 may be applied within the package housing 228 as long as the pressure-sensitive active region (typically on the top side) of the P-cell 226 and its associated bond wires 230 are covered by the gel 232. The Pressure-sensitive gel 232 enables the pressure of the ambient atmosphere to reach the active region of P-cell 226, while protecting P-cell 226 and its associated bond wires 230 from mechanical damage during packaging and environmental damage (e.g., contamination and/or corrosion) when in use. Examples of suitable pressure-sensitive gel 232 are available from Dow Corning Corporation of Midland, Mich. The gel 232=may be dispensed with a nozzle of a conventional dispensing machine, as is known in the art. A lid 234 having an opening or vent hole 236 is mounted on top of the package housing 228 over the gel-covered P-cell 226, thereby providing a protective cover for the P-cell. The vent hole 236 allows the ambient atmospheric pressure immediately outside the pre-packaged pressure sensor 224 and therefore immediately outside the sensor device 200 to reach the pressure-sensitive gel 232 and therethrough the active region of the P-cell 226. Although shown centered in FIG. 2, the vent hole 236 can be located anywhere within the area of the lid 234. The vent hole 236 may be pre-formed in the lid by any suitable fabrication process such as drilling or punching. The lid 234 is formed of a durable and stiff material, such as stainless steel, plated metal, or polymer, so that the P-cell 226 is protected. The lid 234 is sized and shaped depending on the size and shape package housing 228, which is itself sized and shaped depending on the size and shape of the P-cell 226. Accordingly, depending on the implementation, the lid 234 may have any suitable shape, such as round, square, or rectangular.

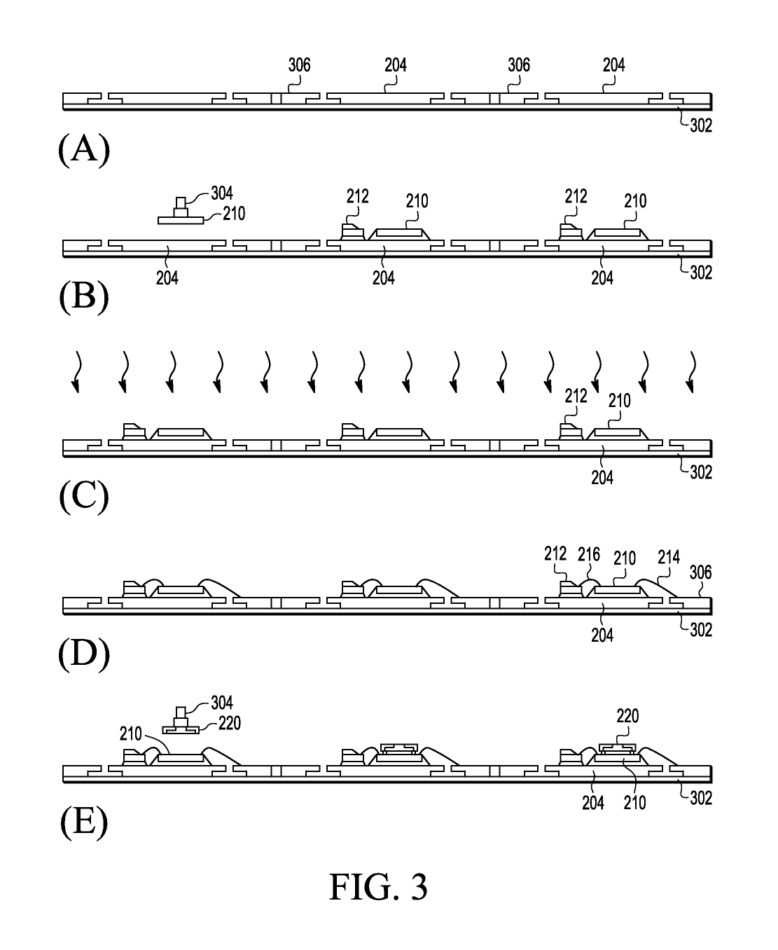

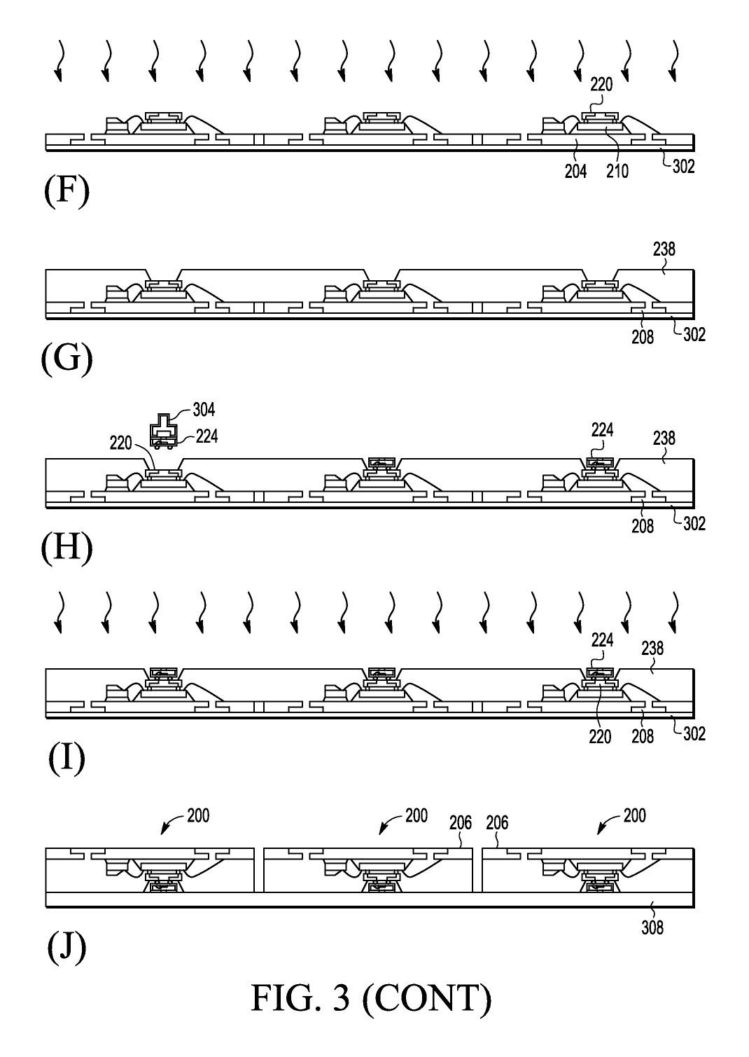

The lead frame 202, MCU 210, G-cell 212, bond wires 214 and 216, and all but a portion of the top surface of the interposer 220 are encapsulated in a molding compound 238. The molding compound 238 may be a plastic, an epoxy, a silica-filled resin, a ceramic, a halide-free material, the like, or combinations thereof, is known in the art. As explained below in the context of FIG. 3(G), depending on the particular implementation, the molding compound 208 of the pre-molded lead frame 202 and the encapsulating molding compound 238 may be applied in a single manufacturing step or in two different manufacturing steps. That is, if applied in a single step then a regular lead frame instead of a pre-molded lead frame is used in the assembly process.

Thus, the pre-packaged pressure sensor 224 is electrically connected to the MCU by way of the bumps 222, interposer 220 and bumps 218. The MCU 210 functions as a controller for both the G-cell 212 and the P-cell 226 by, for example, controlling the operations of and processing signals generated by these two sensor dies. Note that, in some embodiments, the MCU 210 may implement both the functionality of an MCU and that of one or more other sensors, such as an acceleration-sensing G-cell, in which latter case, the G-cell 212 may be omitted. The MCU 210, G-cell 212, and P-cell 226 are well-known components of semiconductor sensor devices and thus detailed descriptions thereof are not necessary for a complete understanding of the invention.

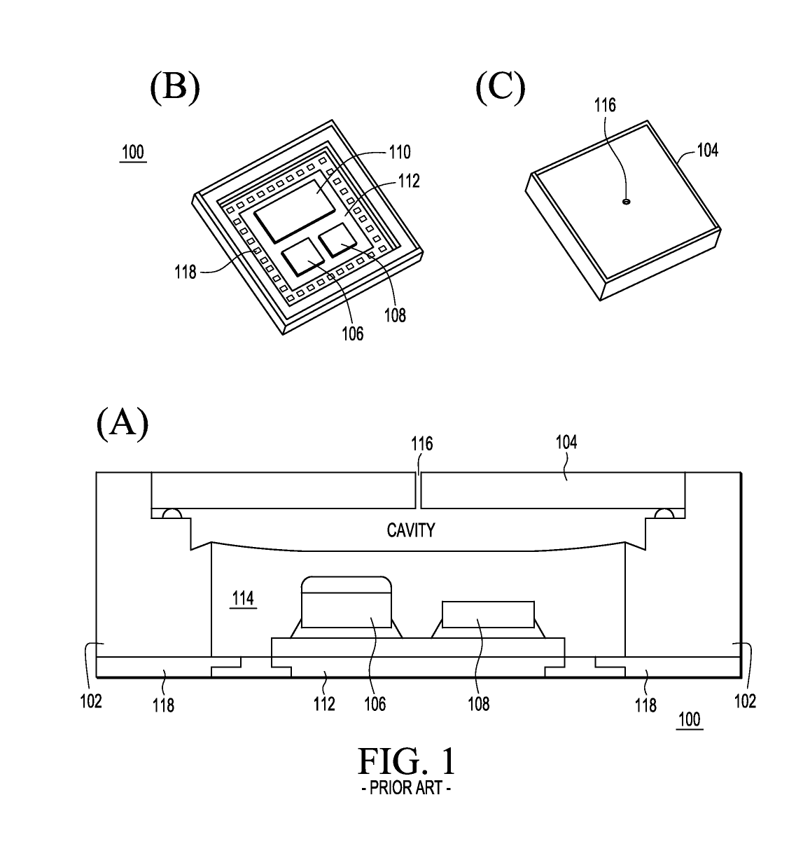

The sensor device 200 can be manufactured with less cost than comparable sensor devices, like the conventional sensor device 100 of FIG. 1 because the sensor device 200 has a smaller lid and uses less pressure-sensitive gel. Furthermore, because the P-cell 226 is pre-packaged within a stand-alone pressure sensor device 224, the pressure sensor device 224 can be tested independently, prior to being packaged within the sensor device 200. The interposer prevents direct mold clamping onto the MCU 210, which reduces the risk of cracks forming in the MCU 210.

FIGS. 3(A)-3(J) illustrate one possible process for manufacturing multiple instances of sensor device 200 of FIG. 2. In particular, FIG. 3(A) shows a cross-sectional side view of die paddles 204 and metal lead structures 306 that will eventually form leads 206 of multiple instances of lead frame 202 of FIG. 2. Note that, later in the manufacturing process, singulation will sever each lead structure 306 into two leads 206, one lead for each of two adjacent instances of lead frame 202. Die paddles 204 and lead structures 306 are all mounted on suitable lead frame tape 302.

FIG. 3(B) shows a cross-sectional side view of conventional pick-and-place machinery 304 placing MCU and G-cell dies 210 and 212 onto the die paddles 204 of FIG. 3(A).

FIG. 3(C) shows a cross-sectional side view of the MCU and G-cell dies 210 and 212 of FIG. 3(B) being oven-cured onto die paddles 204. Note that, depending on the implementation, the attachment or die-bonding of all of the MCU and G-cell dies can be achieved in a single die-bonding process step that includes the curing of the epoxy or other substance (e.g., die-attach tape) used to mount all of those dies in a single pass through a curing cycle (e.g., comprising heating and/or UV irradiation).

FIG. 3(D) shows a cross-sectional side view of the MCU dies 210 of FIG. 3(C) after being wire-bonded to both the G-cell dies 212 and to lead structures 306. Note that (i) the MCU dies can be electrically connected to the lead structures and (ii) the G-cell dies can be electrically connected to the MCU dies all in a single pass though a wire-bonding cycle (or in a single wire-bonding process step).

FIG. 3(E) shows a cross-sectional side view of the pick-and-place machinery 304 placing instances of interposer 220 onto corresponding MCU dies 210 of FIG. 3(D). Note that the MCU bond pads (not explicitly shown) are either plated or non-plated. For non-plated wafers, stud bumping can be performed prior to the placement of the interposers 220.

FIG. 3(F) shows a cross-sectional side view of the interposers 220 of FIG. 3(E) being subjected to reflow or oven-curing for thermo compression bonding, depending on the media of interconnection between the interposers and the MCU dies.

FIG. 3(G) shows a cross-sectional side view of the result of film-assisted encapsulation with pin molding, being applied to the sub-assemblies of FIG. 3(F). Although not explicitly depicted in the figures, film is pressed onto interposers 220, mold pins are pressed on the film, and then molding compound is applied to encapsulate and embed all of the existing elements within molding compound 208/238, while leaving a large area on the top of each interposer 220 exposed. The mold pins and the film prevent the molding compound from seeping onto the exposed areas of the interposers.

One way of applying the molding compound is using a mold insert of a conventional injection-molding machine, as is known in the art. The molding material is typically applied as a liquid polymer, which is then heated to form a solid by curing in a UV or ambient atmosphere. The molding material can also be a solid that is heated to form a liquid for application and then cooled to form a solid mold. Subsequently, an oven is used to cure the molding material to complete the cross linking of the polymer. In alternative embodiments, other encapsulating processes may be used.

Note that, in this implementation, the lead frame molding compound 208 and the encapsulating molding compound 238 result from a single application of molding compound. In an alternative implementation, the lead frame is pre-molded prior to the step of FIG. 3(A), in which case the corresponding step of FIG. 3(G) would involve the application of only molding compound 238. In either case, after encapsulation, the mold pins and the film are removed to produce the structure shown in FIG. 3(G).

FIG. 3(H) shows a cross-sectional side view of the pick-and-place machinery 304 placing instances of pre-packaged pressure sensor 224 onto corresponding interposers 220 of FIG. 3(G). In a preferred embodiment of the invention, the molding compound 238 extends well above a top surface of the interposer 220 such that a cavity in the molding compound 238 is formed over the interposer 220. The pre-packaged pressure sensor 224 is placed in the cavity. In another preferred embodiment, when seated within the cavity, a top of the pre-packaged pressure sensor 224 is flush with a top surface of the molding compound 238.

FIG. 3(I) shows a cross-sectional side view of the pre-packaged pressure sensors 224 of FIG. 3(H) being subjected to reflow or oven-curing for thermo compression bonding, depending on the media of interconnection between the pre-packaged pressure sensors and the interposers.

FIG. 3(J) shows a cross-sectional side view of the structure of FIG. 3(I) after (i) being flipped over and placed onto UV tape 308, (ii) removal of lead frame tape 302, and (iii) performance of saw or laser singulation, during which each lead structure 306 is severed into two leads 206 of adjacent instances of sensor device 200 The resulting structure of FIG. 3(J) comprises multiple instances of semiconductor sensor device 200 of FIG. 2 mounted onto UV tape 308, which can then be safely removed without pulling off any of the pre-packaged pressure sensors 224. Another method of saw singulation is using a jig to hold the structure, in which case the UV tape is not required.

Although not explicitly depicted in the drawings, in real-world manufacturing, a two-dimensional array of different instances of sensor device 200 would be assembled on a multi-device lead frame that consists of a two-dimensional array of different instances of the lead frame structures of FIG. 3(A). After assembly, e.g., using the process depicted in FIGS. 3(A)-3(J), the multiple sensor devices would then be separated, e.g., in a singulation process involving a saw or laser, to form individual instances of sensor device 200.

As used herein, the term “mounted to” as in “a first die mounted to a die paddle” covers situations in which the first die is mounted directly to the lead frame with no other intervening dies or other structures (as in the mounting of MCU 210 to die paddle 204 in FIG. 2) as well as situations in which the first die is directly mounted to another die, which is itself mounted directly to the die paddle. An example of this latter situation would be an embodiment in which a G-cell die is mounted to an MCU die, which is in turn mounted to a die paddle, in which case, the G-cell die could be said to be “mounted to” the die paddle, albeit via the MCU die. Note that “mounted to” also covers situations in which there are two or more intervening dies between the first die and lead frame. Depending on the situation, the term “mounted” can imply electrical connection in addition to physical attachment, where the electrical connection may be provided by one or more bond wires, one or more solder bumps, and/or any other suitable technique.

Although FIG. 2 shows sensor devices 200 having a P-cell and a G-cell, those skilled in the art will understand that, in alternative embodiments, the G-cell and its corresponding bond wires may be omitted.

Although FIG. 2 shows an embodiment in which a G-cell and an MCU are mounted to a die paddle with the electrical interconnection provided by wire-bonding, those skilled in the art will understand that the electrical interconnection between such dies and paddles can, alternatively or additionally, be provided by appropriate flip-chip assembly techniques. According to these techniques, two elements are electrically interconnected through flip-chip bumps attached to one of the elements. The flip-chip bumps may include solder bumps, gold balls, molded studs, or combinations thereof. The bumps may be formed or placed on a semiconductor die using known techniques such as evaporation, electroplating, printing, jetting, stud bumping, and direct placement. The die is flipped, and the bumps are aligned with corresponding contact pads of the other element.

By now it should be appreciated that there has been provided an improved packaged semiconductor sensor device and a method of forming the improved packaged semiconductor sensor device. Circuit details are not disclosed because knowledge thereof is not required for a complete understanding of the invention.

Although the invention has been described using relative terms such as “front,” “back,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the disclosure is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non enabled embodiments and embodiments that correspond to non statutory subject matter are explicitly disclaimed even if they fall within the scope of the claims.

1. A semiconductor sensor device, comprising:
a substrate;
a micro-controller unit (MCU) die mounted on the substrate;
an interposer mounted on the MCU die;
a first molding compound encapsulating the MCU die and a first portion of the interposer, wherein a second portion of the interposer is exposed; and
a pre-packaged pressure sensor mounted on the exposed, second portion of the interposer, wherein the interposer provides electrical interconnection between the MCU die and the pre-packaged pressure sensor.

2. The sensor device of claim 1, wherein the substrate is a lead frame comprising a die paddle and at least one lead, the MCU die is die-bonded to the die paddle, and the MCU die is electrically connected to the at least one lead with a bond wire.

3. The sensor device of claim 2, wherein the die paddle and the at least one lead are embedded in the first molding compound that encapsulates the MCU die and the first portion of the interposer.

4. The sensor device of claim 2, wherein the lead frame comprises a pre-molded lead frame, wherein a second molding compound is formed between the die paddle and the at least one lead before the MCU die is mounted on the die paddle.

5. The sensor device of claim 1, wherein:
the interposer is flip-chip mounted on the MCU die and electrically connected thereto with first bumps; and
the pre-packaged pressure sensor is flip-chip mounted on the interposer and electrically connected thereto with second bumps, whereby the pre-packaged pressure sensor is electrically connected to the MCU by way of the second bumps, the interposer, and the first bumps.

6. The sensor device of claim 1, further comprising another sensor die mounted on the substrate and encapsulated within the first molding compound.

7. The sensor device of claim 6, wherein the another sensor die is an acceleration-sensing die.

8. The sensor device of claim 7, wherein the acceleration-sensing die is electrically connected to the MCU die with bond wires.

9. The sensor device of claim 1, wherein the exposed portion of the interposer is a top surface thereof, and the first molding compound extends above a plane defined by the top surface of the interposer such that a cavity in the first molding compound is formed over the top surface of the interposer, and wherein the pre-packaged pressure sensor is disposed within said cavity.

10. A sensor device, comprising:
a pre-molded lead frame including a die paddle, a plurality of leads surrounding the die paddle, and a first molding compound embedded between the leads and the die paddle;
a micro-controller unit die (MCU) attached to a surface of the die paddle and electrically connected to at least some of the leads with first bond wires;
an interposer mounted on a top surface of the MCU;
first conductive bumps disposed between the interposer and the MCU for allowing for electrical communication therebetween;
a second molding compound that covers the MCU, the first bond wires, and a portion of the interposer;
a pre-packaged pressure sensor mounted on a top, exposed surface of the interposer; and
second conductive bumps disposed between the pre-packaged pressure sensor and the interposer for allowing electrical communication therebetween, wherein the MCU is in communication with the pre-packaged pressure sensor by way of the first bumps, the interposer, and the second bumps.

11. The sensor device of claim 10, wherein the exposed portion of the interposer is a top surface thereof, and the second molding compound extends above a plane defined by the top surface of the interposer such that a cavity in the second molding compound is formed over the top surface of the interposer, and wherein the pre-packaged pressure sensor is disposed within said cavity.

12. The sensor device of claim 11, further comprising:
an acceleration sensing die mounted on the die paddle adjacent to the MCU; and
second bond wires electrically connecting the MCU and the acceleration sensing die.

13. A method for assembling a semiconductor sensor device, the method comprising:
mounting a micro controller unit (MCU) die on a substrate;
mounting an interposer on the MCU die;
encapsulating the MCU die and a first portion of the interposer in a first molding compound, leaving a second portion of the interposer exposed; and
mounting a pre-packaged pressure sensor onto the exposed, second portion of the interposer, wherein the interposer provides electrical interconnection between the MCU die and the pre-packaged pressure sensor.

14. The method of claim 13, wherein:
the substrate is a lead frame comprising a die paddle and a plurality of leads; and
the method further comprises:
die bonding the MCU die to the die paddle; and
electrically connecting the MCU die to the plurality of leads with first bond wires.

15. The method of claim 14, wherein the lead frame comprises a pre-molded lead frame having a second mold compound embedded between the die paddle and the plurality of leads.

16. The method of claim 13, wherein the interposer is mounted to the MCU die with a flip-chip mounting process and the pre-packaged pressure sensor is mounted to the interposer with a flip-chip mounting process.

17. The method of claim 13, further comprising:
mounting an acceleration-sensing die on the substrate proximate to the MCU die; and
electrically connecting the MCU die and the acceleration-sensing die with bond wires, wherein the acceleration-sensing die is covered with the first molding compound during the encapsulation step.

18. The method of claim 13, wherein the encapsulation step comprises using one or both of a mold pin and film to prevent the first molding compound from covering the exposed, second portion of the interposer.

19. The method of claim 18, wherein the exposed portion of the interposer is a top surface thereof, and the first molding compound extends above a plane defined by the top surface of the interposer such that a the mold pin forms a cavity in the first molding compound over the top surface of the interposer, and wherein the pre-packaged pressure sensor is disposed within said cavity.

20. The method of claim 13, wherein the pre-packaged pressure sensor comprises a pressure-sensing die mounted within a package housing, wherein the pressure-sensing die is covered by a pressure-sensitive gel and the package housing is covered by a lid having a vent hole.
